(19) United States
(12) Patent Application Publication
(10) Pub. No.: US 2016/0268165 A1
(43) Pub. Date: Sep. 15, 2016

(54) METHOD FOR MANUFACTURING SEMICONDUCTOR DEVICE

(71) Applicant: KABUSHIKI KAISHA TOSHIBA, Tokyo (JP)

(72) Inventors: Satoshi MATSUI, Yokohama Kanagawa (JP); Mie MATSUO, Kamakura Kanagawa (JP); Chiaki TAKUBO, Sumida Tokyo (JP)

(73) Assignee: KABUSHIKI KAISHA TOSHIBA, Tokyo (JP)

(21) Appl. No.: 14/843,917

(22) Filed: Sep. 2, 2015

Related U.S. Application Data
(60) Provisional application No. 62/131,090, filed on Mar. 10, 2015.

(51) Int. Cl. H01L 21/78; H01L 21/308; H01L 21/268; H01L 21/285; H01L 21/3213; H01L 21/321; H01L 21/3065; H01L 21/306

(52) U.S. Cl. CPC H01L 21/78; H01L 21/3065; H01L 21/3081; H01L 21/30621; H01L 21/3086; H01L 21/28568; H01L 21/28556; H01L 21/2855; H01L 21/32134; H01L 21/321; H01L 21/268; H01L 21/28575

(57) ABSTRACT

According to one embodiment, a method for manufacturing a semiconductor device, includes: selectively forming a plurality of electrode layers on a first surface of a semiconductor substrate, the semiconductor substrate having the first surface and a second surface; and dividing the semiconductor substrate by forming a gap piercing from the first surface to the second surface of the semiconductor substrate, the gap being formed by dry etching the first surface of the semiconductor substrate exposed between the plurality of electrode layers, the plurality of electrode layers being used as masks.

### CROSS-REFERENCE TO RELATED APPLICATIONS

This application is based upon and claims the benefit of priority from U.S. Provisional Patent Application 62/131,090, filed on Mar. 10, 2015; the entire contents of which are incorporated herein by reference.

### FIELD

Embodiments described herein relate generally to a method for manufacturing semiconductor device.

### BACKGROUND

There is a plasma dicing as a method for singulating a semiconductor wafer into a plurality of semiconductor devices. In the plasma dicing, a plurality of mask layers are selectively formed on a semiconductor wafer, the semiconductor wafer exposed from the plurality of mask layers is etched by dry etching, and the semiconductor wafer is singulated. Before singulation, e.g. a MOSFET (Metal Oxide Semiconductor Field Effect Transistor) is provided on the semiconductor wafer by the so-called wafer process. The MOSFET has an upper electrode on an upper surface side and a lower electrode on a rear surface side.

However, when the semiconductor wafer is plasma-diced from the side of the rear surface, a layer to be a lower electrode is formed on the rear surface side of the semiconductor wafer in advance, the layer is patterned, so that the lower electrode is formed. Then, a process of forming mask layers for exposing only dicing lines of the semiconductor wafer on the side of the rear surface of the semiconductor wafer again is required.

### BRIEF DESCRIPTION OF THE DRAWINGS

FIG. 1 is a flowchart showing an example of a method for manufacturing a semiconductor device according to an embodiment;

FIGS. 2A to 3C are schematic sectional views showing an example of the method for manufacturing the semiconductor device according to the embodiment;

FIG. 4 is a schematic plan view showing one example of the method for manufacturing the semiconductor device according to the embodiment;

FIGS. 5A to 8B are schematic sectional views showing patterning of lower electrode layers according to the embodiment;

FIGS. 9A and 9B are schematic sectional views showing a method for manufacturing a semiconductor device according to a first reference example; and

FIGS. 10A to 10D are schematic sectional views showing a method for manufacturing a semiconductor device according to a second reference example.

### DETAILED DESCRIPTION

According to one embodiment, a method for manufacturing a semiconductor device, includes: selectively forming a plurality of electrode layers on a first surface of a semiconductor substrate, the semiconductor substrate having the first surface and a second surface; and dividing the semiconductor substrate by forming a gap piercing from the first surface to the second surface of the semiconductor substrate, the gap being formed by dry etching the first surface of the semiconductor substrate exposed between the plurality of electrode layers, the plurality of electrode layers being used as masks.

Embodiments will now be described with reference to the drawings. In the following description, like members are labeled with like reference numerals and the description of the members once described will be appropriately omitted.

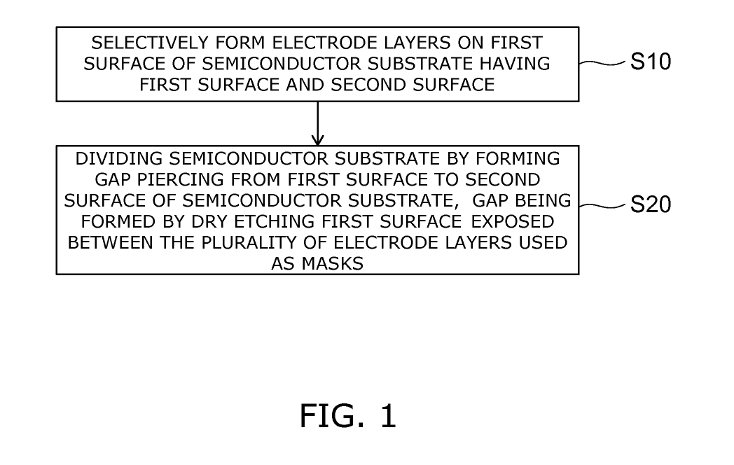

FIG. 1 is a flowchart showing an example of a method for manufacturing a semiconductor device according to the embodiment.

In the method for manufacturing a semiconductor device according to the embodiment, a plurality of electrode layers are selectively formed on a first surface of a semiconductor substrate having the first surface and a second surface (step S10).

Then, the semiconductor substrate is divided by forming a gap piercing from the first surface to the second surface of the semiconductor substrate, the gap is formed by dry etching the first surface of the semiconductor substrate exposed between the plurality of electrode layers, and the plurality of electrode layers are used as masks (step S20).

As below, the method for manufacturing the semiconductor device according to the embodiment will be specifically described.

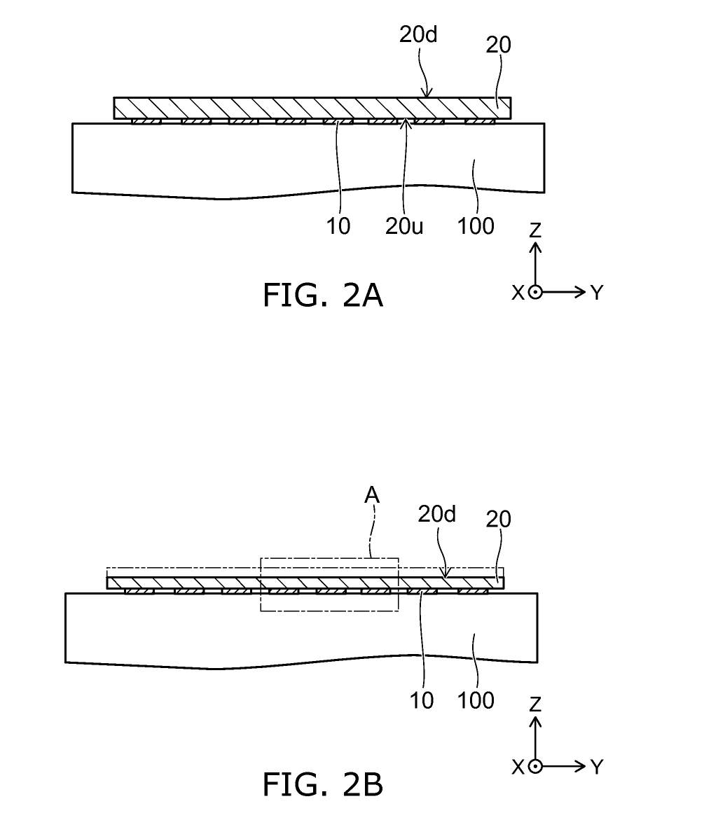

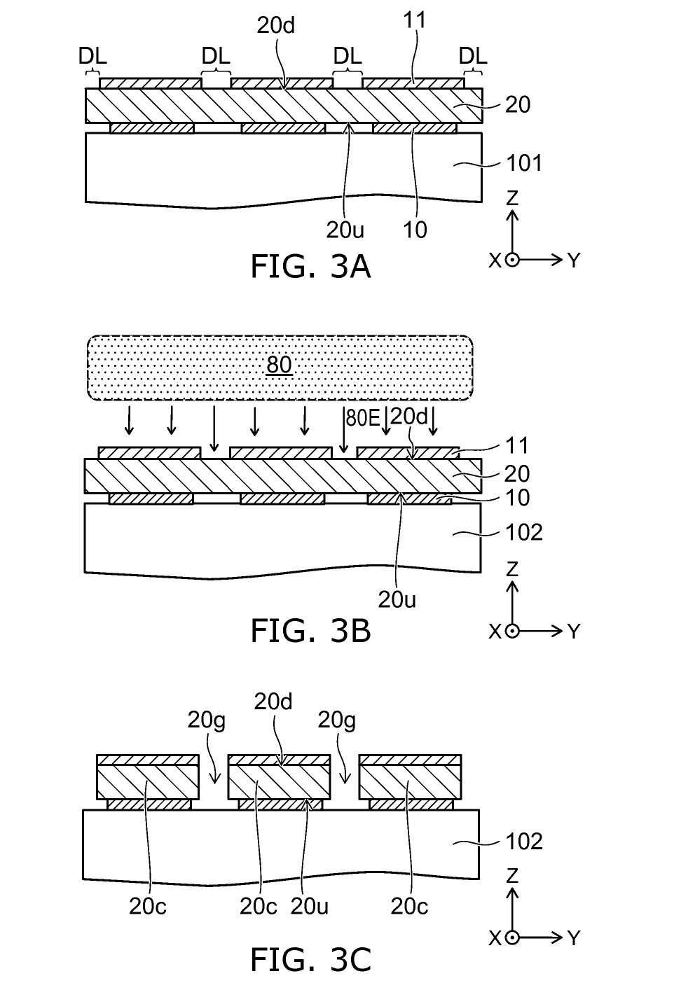

FIGS. 2A to 3C are schematic sectional views showing an example of the method for manufacturing the semiconductor device according to the embodiment. XYZ-coordinate systems are introduced to the drawings shown in the embodiment.

For instance, as shown in FIG. 2A, a semiconductor substrate 20 is set with its face down on a support 100. The support 100 is e.g. a grind tape. The semiconductor substrate 20 shown in FIG. 2A is e.g. a semiconductor wafer. When the semiconductor substrate 20 is seen from a Z-direction, the outer shape of the semiconductor substrate 20 is a circular shape. The semiconductor substrate 20 includes one of e.g. silicon (Si), silicon carbide (SiC), gallium nitride (GaN), and gallium arsenide (GaAs).

The semiconductor substrate 20 has a first surface (hereinafter, e.g. a lower surface 20d) and a second surface (hereinafter, e.g. an upper surface 20u). The semiconductor substrate 20 is set on the support 100 with the upper surface 20u directed toward the support 100.

The direction from the lower surface 20d to the upper surface 20u is e.g. the Z-direction and the direction intersecting with the Z-direction is e.g. an X-direction or a Y-direction in the embodiment.

The wafer process has been already performed on the upper surface 20u side of the semiconductor substrate 20, and e.g. at least one parts of semiconductor elements have been formed on the upper surface 20u. Within the semiconductor substrate 20, regions in which at least one parts of semiconductor elements are formed are referred to as “device regions”.

For instance, when the semiconductor device is a MOSFET including a source region, a base region, a drift region, a drain region, a gate electrode, and a gate insulating film, the source region, the base region, the gate electrode, and the gate insulating film, etc. (hereinafter referred to as “source region etc.”) are provided on the side of the upper surface 20u of the semiconductor substrate 20. Further, e.g. the drain region is provided on the side of the lower surface 20d of the semiconductor substrate 20. The drift region is provided between the drain region and the source region etc.

For instance, the semiconductor device is an IGBT including an n-type emitter region, a p-type base region, an n-type base region, a p-type collector region, a gate electrode, and a gate insulating film, the n-type emitter region, the p-type base region, the gate electrode, and the gate insulating film, etc. (hereinafter referred to as “emitter region etc.”) are provided on the side of the upper surface 20u of the semiconductor substrate 20. Further, the p-type collector region is provided on the side of the lower surface 20d of the semiconductor substrate 20. The n-type base region is provided between the p-type collector region and the n-type emitter region etc.

For instance, when the semiconductor device is a diode including a p-type region and an n-type region, the p-type region is provided on the side of the upper surface 20u of the semiconductor substrate 20. The n-type region is provided on the side of the lower surface 20d of the semiconductor substrate 20.

For instance, when the semiconductor device is a light emitting device such as an LED (Light Emitting Diode), a light emitting part and cladding layers sandwiching the light emitting part are provided on the side of the upper surface 20u of the semiconductor substrate 20.

Further, interlayer insulating films, via electrodes, interconnections, etc. may be provided on the side of the upper surface 20u of the semiconductor substrate 20. Or, passive devices such as resistors and capacitors may be provided on the side of the upper surface 20u of the semiconductor substrate 20. In the embodiment, the semiconductor substrate 20 includes not only the semiconductor devices but also the interlayer insulating films, via electrodes, interconnections, electrode pads, etc.

A plurality of upper electrode layers 10 are selectively provided on the upper surface 20u of the semiconductor substrate 20. When the device is a MOSFET, the upper electrode layer 10 is e.g. a source electrode or a gate pad, when the device is an IGBT, e.g. an emitter electrode or a gate pad, when the device is a diode, e.g. an anode electrode, and when the device is an LED, corresponds to an upper electrode layer of the LED.

Then, as shown in FIG. 2B, the lower surface 20d of the semiconductor substrate 20 is ground by back grind or the like. Thereby, the thickness of the semiconductor substrate 20 becomes thinner. Further, on the lower surface 20d of the semiconductor substrate 20 ground by back grind or the like, polishing such as polishing grind may be performed.

The next process will be described using a drawing in which a part surrounded by A in FIG. 2B is enlarged.

Then, as shown in FIG. 3A, a plurality of lower electrode layers 11 are selectively formed on the lower surface 20d of the semiconductor substrate 20 disposed on a support 101. The lower electrode layers 11 are formed by e.g. sputtering, CVD (Chemical Vapor Deposition), vacuum evaporation, or the like.

As a material for the lower electrode layers 11, a material having higher resistance to an etching gas at dry etching is selected. The material will be described later. For instance, as the material of the lower electrode layers 11, one of gold (Au), platinum (Pt), and palladium (Pd) is selected when the etching gas includes a gas including fluorine.

The lower electrode layer 11 may be a single metal layer or a metal layer in which a plurality of layers (e.g. metal layers) are stacked. When the lower electrode layer 11 includes a plurality of metal layers, a layer including one of gold (Au), platinum (Pt), and palladium (Pd) is exposed to the etching gas on a surface of the lower electrode layer 11. As a foundation layer of the uppermost layer, e.g. a layer including a metal such as nickel (Ni) may be used.

The lower electrode layers 11 are patterned by e.g. one method of liftoff, laser grooving, blade dicing, wet etching, and methods will be described later.

Further, each of the plurality of lower electrode layers 11 is not formed on a dicing (dividing) line (DL) of the semiconductor substrate 20. The dicing line (DL) is a region to be removed by dicing (dividing). Therefore, the device, the interlayer insulating film, the via electrode, the interconnection, the electrode pad, etc. may not be disposed on the dicing line (DL). Further, the plurality of lower electrode layers 11 are formed so that each of the plurality of lower electrode layers 11 may be located on each of the plurality of upper electrode layers 10. The width of the dicing line (DL) in the X-direction or the Y-direction is e.g. 10 μM or less.

Furthermore, an area of the section by cutting of each of the plurality of upper electrode layers 10 in the X-direction and the Y-direction is smaller than an area of the section by cutting of each of the plurality of lower electrode layers 11 in e.g. the X-direction and the Y-direction.

Then, as shown in FIG. 3B, the semiconductor substrate 20 with the plurality of lower electrode layers 11 is disposed on a support 102 of a plasma dicing apparatus (not shown). For instance, the semiconductor substrate 20 is mounted on the support 102 with the upper surface 20u of the semiconductor substrate 20 directed toward the support 102. The support 102 is a tape, an electrostatic chuck, a metallic stage, or the like.

Then, a gas for etching is introduced into the plasma dicing apparatus and discharge for the etching gas is incepted. Thereby, plasma 80 is generated within the plasma dicing apparatus. The plasma 80 includes an etchant 80E etc. that can etch the semiconductor substrate 20. The lower surface of the semiconductor substrate 20 exposed from the lower electrode layers 11 is exposed to the etchant 80E etc. That is, the lower surface 20d of the semiconductor substrate 20 exposed from the plurality of lower electrode layers 11 is dry etched.

The dry etching is e.g. RIE (Reactive Ion Etching). For instance, a predetermined bias (e.g. negative bias) may be applied to the semiconductor substrate 20 while the plasma 80 is generated. Or, a self-bias may be applied to the semiconductor substrate 20 while the plasma 80 is generated.

Thereby, ions in the plasma 80 are accelerated toward the semiconductor substrate 20. When the ions in the plasma 80 collide with the semiconductor substrate 20, chemical reaction between the ions and the etching gas occurs in the irradiated part of the semiconductor substrate 20, and etching of the semiconductor substrate 20 progresses.

In the dry etching, the semiconductor substrate 20 is dry etched using a gas including e.g. fluorine. The gas includes e.g. SF₆ and CF₄.

Here, the metal having higher etching resistance to the gas including fluorine, e.g. one of gold (Au), platinum (Pt), and palladium (Pd) is exposed on the uppermost surface of the lower electrode layer 11. Accordingly, the lower electrode layers 11 are hard to be etched, and the semiconductor substrate 20 exposed from the lower electrode layers 11 is selectively etched.

FIG. 3C shows a state after etching.

As shown in FIG. 3C, the semiconductor substrate 20 is divided into individual chip portions 20c by plasma dicing. The semiconductor substrate 20 is divided with gaps 20g. The gaps 20g pierce from the side of the lower surface 20d to the side of the upper surface 20u of the semiconductor substrate 20. Thereby, a semiconductor device including the upper electrode layer 10, the lower electrode layer 11, and the chip portion 20c is obtained.

When the device is a MOSFET, the lower electrode layer 11 formed on the lower surface 20d of the chip portion 20c is e.g. a drain electrode, when the device is an IGBT, e.g. a collector electrode, when the device is a diode, e.g. a cathode electrode, and when the device is an LED, corresponds to e.g. a lower electrode of the LED.

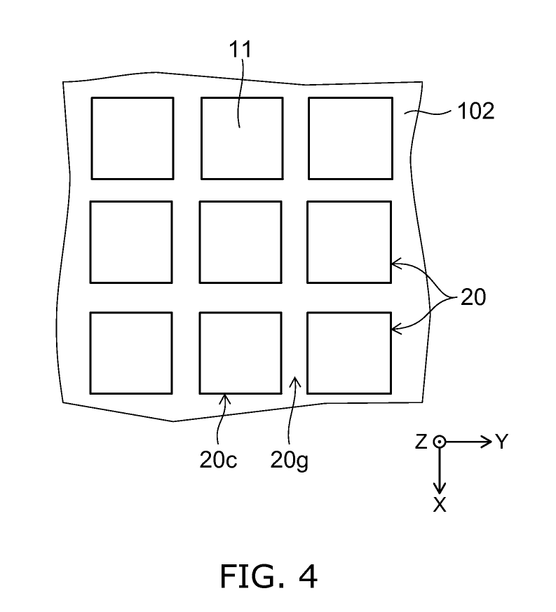

FIG. 4 is a schematic plan view showing one example of the method for manufacturing the semiconductor device according to the embodiment.

FIG. 4 schematically shows a state after etching of the semiconductor substrate 20 as seen from the Z-direction. For instance, the semiconductor substrate 20 is divided with the gap 20g in the X-direction or the Y-direction. Each divided chip portion 20c is surrounded by the gaps 20g. Then, the respective semiconductor devices are picked up from the support 102.

Here, a method for patterning the lower electrode layers 11 will be described.

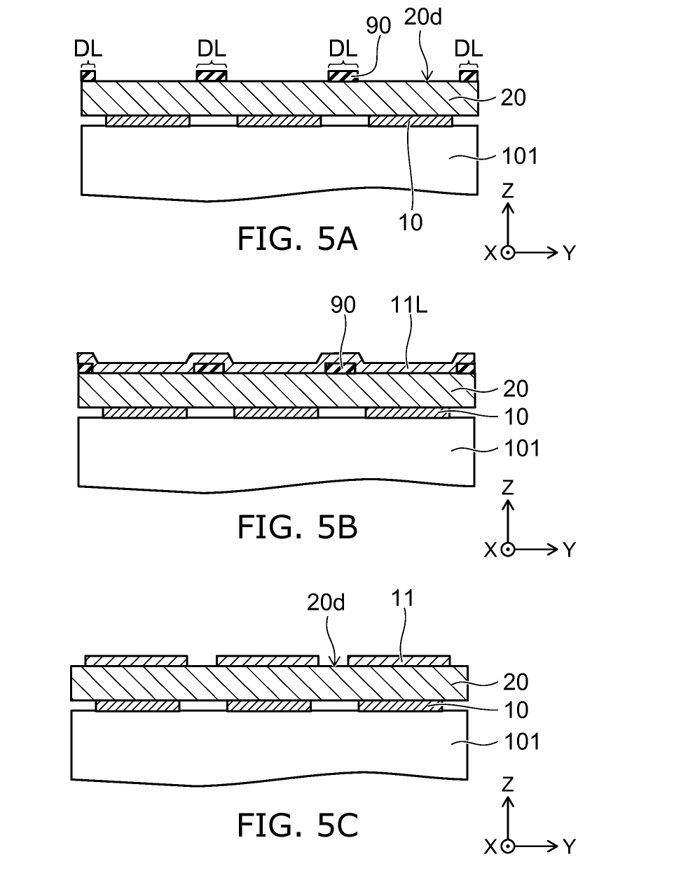

FIGS. 5A to 8B are schematic sectional views showing patterning of the lower electrode layers according to the embodiment.

FIGS. 5A to 5C show a process in which the lower electrode layers 11 are patterned by liftoff.

For instance, as shown in FIG. 5A, resist layers 90 are patterned along the dicing lines DL of the lower surface 20d of the semiconductor substrate 20. The patterning of the resist layers 90 is performed by e.g. PEP (Photo Engraving Process).

Then, as shown in FIG. 5B, a lower electrode layer 11L is formed on the resist layers 90 and the lower surface 20d of the semiconductor substrate 20. A material for the lower electrode layer 11L is the same as that for the lower electrode layers 11. Then, the lower electrode layer 11L is exposed to an organic solvent, e.g. ultrasonic wave is applied to the resist layers 90, and the resist layers 90 are removed.

Thereby, as shown in FIG. 5C, the resist layers 90 and the lower electrode layer 11L on the resist layers 90 are removed, and the lower electrode layers 11 are left on the lower surface 20d of the semiconductor substrate 20. That is, the lower electrode layers 11 are patterned on the lower surface 20d of the semiconductor substrate 20.

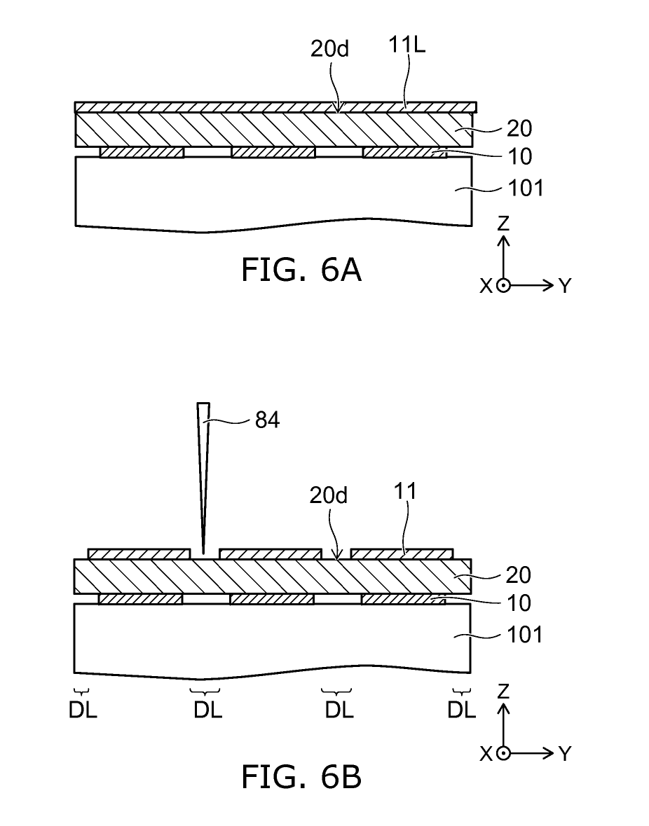

FIGS. 6A and 6B show a process in which the lower electrode layer 11L is patterned by laser grooving.

For instance, as shown in FIG. 6A, the lower electrode layer 11L is formed on the lower surface 20d of the semiconductor substrate 20.

Then, as shown in FIG. 6B, a laser beam 84 is applied along the dicing lines DL and the lower electrode layer 11L on the dicing lines is selectively evaporated. Thereby, the lower electrode layers 11 are patterned on the lower surface 20d of the semiconductor substrate 20.

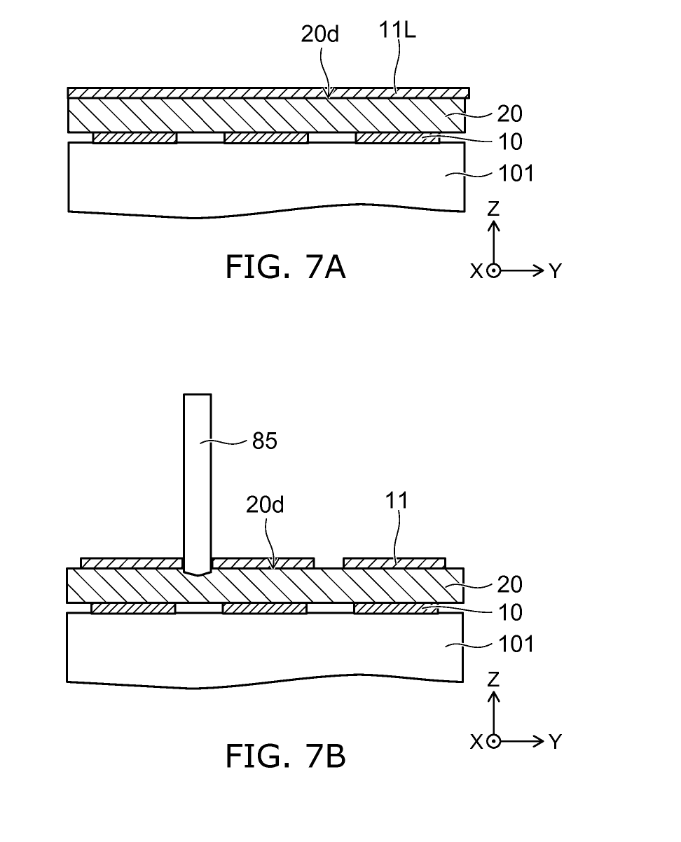

FIGS. 7A and 7B show a process in which the lower electrode layer 11L is patterned by blade dicing.

For instance, as shown in FIG. 7A, the lower electrode layer 11L is formed on the lower surface 20d of the semiconductor substrate 20.

Then, as shown in FIG. 7B, a dicing blade 85 is applied along the dicing lines DL to the lower electrode layer 11L, and the lower electrode layer 11L on the dicing lines DL is selectively removed. Thereby, the lower electrode layers 11 are patterned on the lower surface 20d of the semiconductor substrate 20. In the blade dicing, parts on the side of the lower surface 20d of the semiconductor substrate 20 may be removed along the dicing lines DL. Thereby, time required for plasma dicing comes to be shorter.

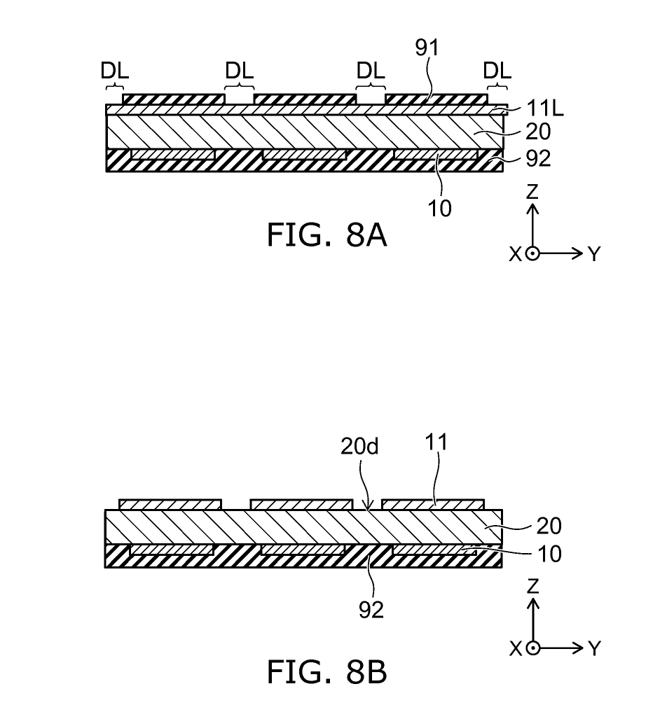

FIGS. 8A and 8B show a process in which the lower electrode layer 11L is patterned by wet etching.

For instance, as shown in FIG. 8A, the lower electrode layer 11L is formed on the lower surface 20d of the semiconductor substrate 20. Then, resist layers 91 are patterned on the lower electrode layer 11L. Here, the resist layers 91 are not formed on the dicing lines DL. The upper surface 20u side of the semiconductor substrate 20 is covered by a resist layer 92.

Then, as shown in FIG. 8B, the lower electrode layer 11L exposed from the resist layers 91 is removed by wet etching using a chemical solution. Then, the resist layers 91 are removed. Thereby, the lower electrode layers 11 are patterned on the lower surface 20d of the semiconductor substrate 20.

Methods for manufacturing semiconductor devices according to reference examples will be described before description of the effects of the embodiment.

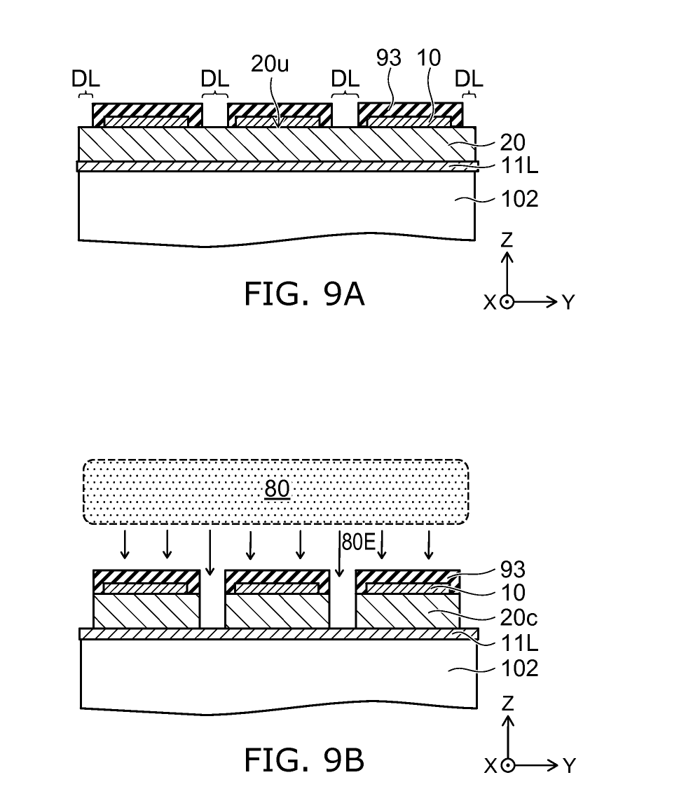

FIGS. 9A and 9B are schematic sectional views showing a method for manufacturing a semiconductor device according to the first reference example.

For instance, as shown in FIG. 9A, mask layers 93 are patterned on the upper surface 20u side of the semiconductor substrate 20. The mask layers 93 are not formed on the dicing lines DL. Upper electrode layers 10 are selectively provided on the upper surface 20u of the semiconductor substrate 20. A lower electrode layer 11L is provided on the lower surface 20d of the semiconductor substrate 20.

Then, as shown in FIG. 9B, the semiconductor substrate 20 is divided by plasma dicing from the side of the upper surface 20u of the semiconductor substrate 20, using a gas including a fluorine.

However, in the first reference example, the lower electrode layer 11L on the dicing lines DL is left after plasma dicing when the lower electrode layer 11L includes a material that cannot be etched by the gas including fluorine.

In the first reference example, another process of sandblasting or the like is required to remove the lower electrode layer 11L on the dicing lines DL. Further, the removed lower electrode layer 11L may become residues, flakes, or the like. And the residues, flakes, or the like may attach to the semiconductor devices. In this case, the semiconductor devices may be short-circuited.

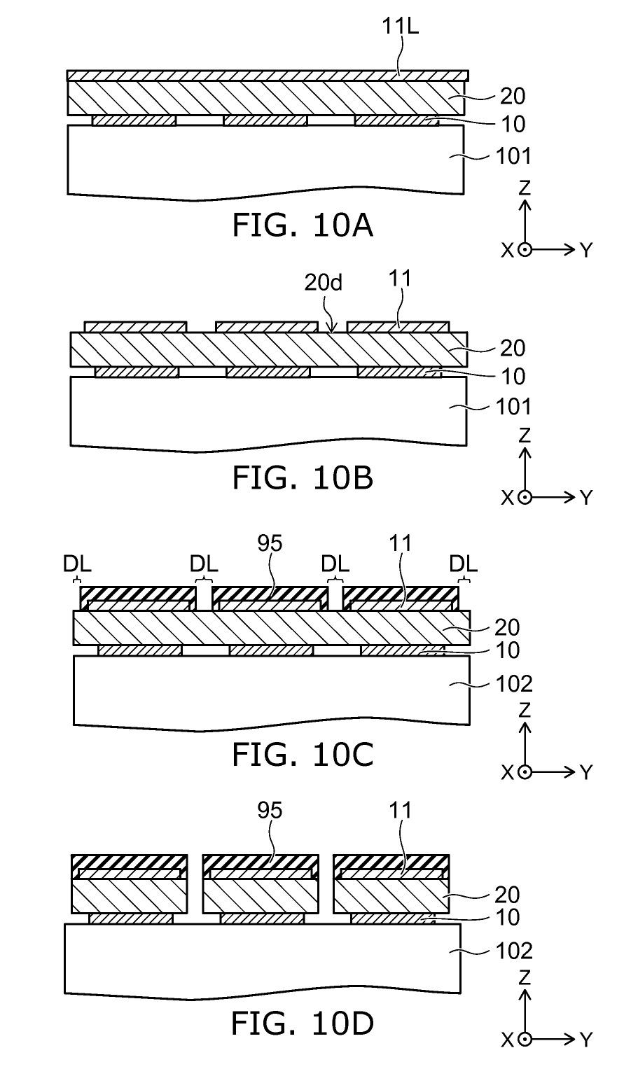

FIGS. 10A to 10D are schematic sectional views showing a method for manufacturing a semiconductor device according to the second reference example.

For instance, as shown in FIG. 10A, a lower electrode layer 11L is formed on the lower surface 20d of the semiconductor substrate 20. Here, a material for the lower electrode layer 11L includes e.g. W (tungsten), titanium (Ti).

Then, as shown in FIG. 10B, the lower electrode layer 11L is patterned to be a plurality of lower electrode layers 11. The patterning of the lower electrode layer 11L is performed using one of laser grooving, blade dicing, and wet etching. Or, at the phase illustrated in FIG. 10A, the lower electrode layers 11 may be patterned in advance by liftoff. The dicing lines DL are exposed from the lower electrode layers 11.

Here, in the second reference example, W (tungsten), titanium (Ti) is used as the material for the lower electrode layer 11L. Accordingly, in the second reference example, the resistance to the gas including fluorine of the lower electrode layers 11 is lower than the resistance to the gas of the embodiment.

Therefore, as shown in FIG. 10C, mask layers 95 that protect the lower electrode layers 11 and expose the dicing lines DL are required to perform plasma dicing of the semiconductor substrate 20 from the side of the lower surface 20d of the semiconductor substrate 20. The mask layers 95 are e.g. resist layers. The mask layers 95 are formed by e.g. PEP. Then, as shown in FIG. 10D, plasma dicing is performed on the semiconductor substrate 20 exposed from the mask layers 95.

However, in the second reference example, after the formation of the lower electrode layers 11, the formation of the mask layers 95 that protect the lower electrode layers 11 and expose the dicing lines DL is required. Thereby, in the second reference example, the manufacturing cost rises.

On the other hand, in the embodiment, the semiconductor substrate 20 is singulated by plasma dicing directly using the lower electrode layers 11 as the mask layers. Therefore, the formation of the mask layers 95 is not required after the formation of the lower electrode layers 11. Thereby, the lower cost than that of the second reference example is realized in the embodiment.

Further, the lower electrode layers 11 are used as the mask layers in the embodiment, and thus, no resist layers exist on the lower electrode layers 11 after plasma dicing. If the resist layers are left on the lower electrode layers 11, a process of removing the resist layers on the lower electrode layers 11 with an organic solvent is required. Here, when the support 102 is e.g. a tape and the tape is exposed to the organic solvent, adhesion between the tape and the semiconductor devices may be weaker and the semiconductor devices may be separated from the tape.

On the other hand, in the embodiment, no resist layers exist on the lower electrode layers 11 after the plasma dicing. Therefore, the process of removing the resist layers on the lower electrode layers 11 with the organic solvent is not required.

Further, liftoff, laser grooving, or blade dicing may be used without the existence of the resist layers on the lower electrode layers 11 after the patterning of the lower electrode layer 11L in the embodiment. That is, the degree of freedom of selection of the method for patterning the lower electrode layer 11L increases in the embodiment.

Furthermore, gold (Au), platinum (Pt), or palladium (Pd) having higher resistance to the gas including fluorine is used as the material for the lower electrode layers 11 in the embodiment. For instance, the resistance to the gas including fluorine is higher when copper (Cu) is used as the material for the lower electrode layers 11. However, fluoride is produced on the surface of the copper (Cu) after plasma dicing. When fluoride is produced on the surface of the lower electrode layers 11, wettability of solder becomes lower and soldering of the lower electrode layers 11 to a substrate (e.g. a lead frame) becomes harder.

Therefore, it is favorable to use gold (Au), platinum (Pt), or palladium (Pd) having higher resistance to the gas including fluorine and not allowing fluoride produced on the surface as the material for the lower electrode layers 11.

Further, there is a dicing method using a dicing blade for singulating the semiconductor substrate. However, in the method, the width of the dicing line should be set to be not less than the width of the dicing blade (50 μm or more). Therefore, it is impossible to set the width of the dicing line to be less than the width of the dicing blade. Further, cracking may occur in the side wall of the semiconductor substrate due to contact between the dicing blade and the side wall of the semiconductor substrate. Therefore, it is impossible to dispose the device region close to the side wall of the semiconductor substrate. That is, according to the method, the occupied area of the device region is not increased.

On the other hand, as the method for singulating the semiconductor substrate 20, plasma dicing is employed in the embodiment. According to the method, the width of the dicing line can be set to be no more than the width of the dicing blade. For instance, the width of the dicing line may be set to be 10 μm or less as one example. Further, the dicing blade is not used, thus, cracking is harder to occur in the side wall of the semiconductor substrate 20 (chip portion 20c). Thereby, the device region may be disposed close to the side wall of the chip portion 20c. That is, according to the embodiment, the occupied area of the device region is increased. In other words, according to the embodiment, the number of semiconductor devices that can be extracted from one semiconductor wafer is increased.

In the above described embodiment, “on” of the expression of “part A is provided on part B” may be used for expressing not only that part A is provided on part B in contact with part B but also that part A is provided above part B without contact with part B. Further, “part A is provided on part B” may be applied to the case where part A and part B are inverted and part A is located under part B and the case where part A and part B are arranged side by side. This is because, when the semiconductor device according to the embodiment is rotated, the structure of the semiconductor device is unchanged before and after the rotation.

As above, the embodiment has been described with reference to the specific examples. However, the embodiment is not limited to the specified examples. That is, the scope of the embodiment includes the specific examples with design changes appropriately made by a person skilled in the art as long as they have the features of the embodiment. The respective elements of the respective specific examples, their arrangements, materials, conditions, shapes, sizes, etc. are not limited to those illustrated but may be appropriately changed.

Further, the above described respective elements of the respective embodiments may be combined as much as technically possible and the scope of the embodiment includes the combinations as long as they have the features of the embodiment. In addition, it would be understood that a person skilled in the art may achieve various modified examples and altered examples within the spirit of the embodiment and these modified examples and altered examples may belong to the scope of the embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing a semiconductor device comprising:
selectively forming a plurality of electrode layers on a first surface of a semiconductor substrate, the semiconductor substrate having the first surface and a second surface; and
dividing the semiconductor substrate by forming a gap piercing from the first surface to the second surface of the semiconductor substrate, the gap being formed by dry etching the first surface of the semiconductor substrate exposed between the plurality of electrode layers, the plurality of electrode layers being used as masks.

2. The method according to claim 1, wherein
the plurality of electrode layers include one of gold (Au), platinum (Pt), and palladium (Pd).

3. The method according to claim 1, wherein
a layer including one of gold (Au), platinum (Pt), and palladium (Pd) of the electrode layer is exposed on surfaces of the plurality of electrode layers.

4. The method according to claim 1, wherein
one of the plurality of electrode layers has a plurality of layers, an uppermost layer of the one of the plurality of electrode layers includes one of gold (Au), platinum (Pt), and palladium (Pd).

5. The method according to claim 1, wherein
the semiconductor substrate is dry etched by using a gas including fluorine.

6. The method according to claim 4, wherein
the semiconductor substrate is dry etched while a bias is applied to the semiconductor substrate.

7. The method according to claim 1, wherein
the plurality of electrode layers are selectively formed on the first surface of the semiconductor substrate by using liftoff.

8. The method according to claim 1, wherein
the plurality of electrode layers are selectively formed on the first surface of the semiconductor substrate by using laser grooving.

9. The method according to claim 1, wherein
the plurality of electrode layers are selectively formed on the first surface of the semiconductor substrate by using blade dicing.

10. The method according to claim 1, wherein
the plurality of electrode layers are selectively formed on the first surface of the semiconductor substrate by using wet etching.

11. The method according to claim 1, wherein
one of the plurality of electrode layers is a lower electrode layer of a semiconductor device.

12. The method according to claim 11, further comprising: forming an upper electrode on the second surface of the semiconductor substrate before forming the lower electrode layer.

13. The method according to claim 12, wherein
an area of the upper electrode is smaller than an area of the lower electrode layer.

14. The method according to claim 11, further comprising: forming semiconductor elements on the second surface of the semiconductor substrate before forming the lower electrode layer.

15. The method according to claim 1, wherein
a distance between an adjacent electrode layers of the plurality of electrode layers is 10 μm or less.
